(19) United States
(12) Patent Application Publication
(10) Pub. No.: US 2025/0323210 A1
(43) Pub. Date: Oct. 16, 2025

(54) MANUFACTURING METHOD AND JOINING METHOD OF JOINED BODY

(71) Applicant: NGK INSULATORS, LTD., Nagoya-shi (JP)

(72) Inventors: Takahiro YAMADERA, Nagoya-shi (JP); Keita IWAMA, Fujiyoshida -shi (JP)

(21) Appl. No.: 19/250,217

(22) Filed: Jun. 26, 2025

Related U.S. Application Data
(63) Continuation of application No. PCT/JP2023/045518, filed on Dec. 19, 2023.

(30) Foreign Application Priority Data
Jan. 27, 2023 (JP) 2023-011416

(51) Int. Cl. H01L 23/00; H10N 30/03

(52) U.S. Cl. CPC H01L 24/83; H10N 30/03; H01L 2224/83896

(57) ABSTRACT

A method for manufacturing a joined body, includes: an activating step of activating respective surfaces of a first substrate and a second substrate having the surfaces each including SiO₂ as a main component by a plasma; a joining step of joining the activated surfaces of the first substrate and the second substrate at a degree of vacuum of 1 mbar or more and 400 mbar or less; and a heating step of heating the first substrate and the second substrate joined with each other. As a result of this, the manufacturing method and the joining method of a joined body capable of combining the reduction of generation of voids and the joint strength are provided.

### CROSS-REFERENCE TO RELATED APPLICATION

This application is a continuation application of PCT/JP2023/045518, filed on Dec. 19, 2023, which claims the benefit of priority of Japanese Patent Application No. JP2023-011416, filed on Jan. 27, 2023, the entire contents of which are incorporated herein by reference.

### TECHNICAL FIELD

The present invention relates to a manufacturing method and a joining method of a joined body.

### BACKGROUND ART

For the purpose of implementing a high performance semiconductor element, for example, a SOI substrate including a high resistance Si/SiO₂ thin film/Si thin film has been widely used. For implementing a SOI substrate, plasma activation has been used. With this method, a substrate can be joined at relatively lower temperatures (400° C.). Further, aiming at the improvement of the characteristics of a piezoelectric device, a composite substrate including a Si/SiO₂ thin film/piezoelectric thin film similar to a SOI substrate has been proposed.

PTL 1 discloses a method for manufacturing a composite wafer. The method for manufacturing a composite wafer includes at least a step of injecting a hydrogen atom ion or a hydrogen molecule ion from the surface, and forming an ion implantation layer in the inside of an oxide single crystal wafer; a step of subjecting at least one of the ion-implanted surface of the oxide single crystal wafer and the surface of the support wafer to a surface activation treatment; a step of bonding the ion-implanted surface of the oxide single crystal wafer and the surface of the support wafer, and obtaining a joined body; a step of heat treating the joined body at a temperature of equal to or higher than 90° C., and not causing cracking; and a step of irradiating the heat-treated joined body with a visible light, and obtaining an oxide single crystal thin film peeled along the ion implantation layer, and transferred onto the support wafer.

### CITATION LIST

### Patent Literature

PTL 1: Japanese Patent Application Publication No. 2016-225537

### SUMMARY OF INVENTION

### Technical Problem

In order to manufacture a substrate of a structure of a Si substrate/SiO₂ thin film/piezoelectric thin film, for example, SiO₂ formed at a Si substrate, and SiO₂ formed at a piezoelectric material are subjected to plasma activation, and bonding thereof is performed.

Then, an annealing treatment is performed, thereby forming a covalent bond via the OH group generated by plasma activation for improving the joint strength. However, at this step, when moisture is present excessively at the joint interface, the moisture may be generated in a form of a void after heating, so that there is room for improvement. On the other hand, when the moisture at the joint interface becomes deficient, the joint strength becomes deficient.

It is an object of the present invention to provide a manufacturing method and a joining method of a joined body, the method being capable of combining the reduction of generation of voids and the joint strength.

### Solution to Problem

In order to solve the foregoing problem, the present invention provides a method for manufacturing a joined body, the method including: an activating step of activating respective surfaces of a first substrate and a second substrate having the surfaces each including SiO₂ as a main component by a plasma; a joining step of joining the surfaces of the first substrate and the second substrate at a degree of vacuum of 1 mbar or more and 400 mbar or less; and a heating step of heating the first substrate and the second substrate joined with each other in this order.

Further, the present invention provides a joining method including an activating step of activating respective surfaces of a first SiO₂ layer and a second SiO₂ layer by a plasma; a joining step of joining the first SiO₂ layer and the second SiO₂ layer at a degree of vacuum of 1 mbar or more and 400 mbar or less; and a heating step of heating the joined first SiO₂ layer and second SiO₂ layer joined with each other, and removing water generated at a joint surface thereof, in this order.

### Advantageous Effects of Invention

The present invention can provide a manufacturing method and a joining method of a joined body, the methods being capable of combining the reduction of generation of voids with the joint strength.

### BRIEF DESCRIPTION OF DRAWINGS

FIG. 1 is a view showing a joined body of the present embodiment.

FIG. 2 is a flowchart for illustrating a method for manufacturing a joined body 1.

FIGS. 3A to 3E are each a view showing a state corresponding to each step shown in FIG. 2.

FIG. 4 is a view showing the results of Example 1.

FIGS. 5A to 5C are each a view showing the results of Comparative Examples 1 to 3.

FIG. 6 is a view showing the relationship between the degree of vacuum and the number of voids.

### DESCRIPTION OF EMBODIMENTS

Below, referring to the accompanying drawings, embodiments of the present invention will be described in details.

### Description of Configuration of Joined Body

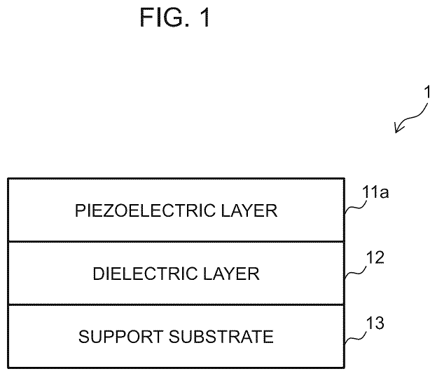

FIG. 1 is a view showing a joined body 1 of the present embodiment.

The shown joined body 1 has a structure in which a piezoelectric layer 11a, a dielectric layer 12, and a support substrate 13 are stacked in this order from the upper part in the drawing.

The piezoelectric layer 11a is a layer including a piezoelectric material. The piezoelectric material is selected according to the application in which the joined body 1 is used. The piezoelectric materials may include, but are not limited to, for example, LiNbO₃ (LN) and LiTaO₃ (LT). Silicon (Si), gallium arsenide (GaAs), silicon carbide (SiC), gallium nitride (GaN), zinc oxide (ZnO), solid solution ceramics (PZT), or the like is appropriately selected.

The dielectric layer 12 is the layer to be arranged under the piezoelectric layer 11a. In the present embodiment, the dielectric layer 12 includes SiO₂ as the main component. Namely, the dielectric layer 12 can also be said to be a SiO₂ film or a SiO₂ layer.

The support substrate 13 will serve as the support of the whole joined body 1. Further, the support substrate 13 is joined with the piezoelectric layer 11a via the dielectric layer 12. As the support substrate 13, a given proper substrate can be used. The support substrate 13 may include a single crystalline body, or may include a polycrystalline body. Alternatively, the support substrate 13 may include a metal.

The material configuring the support substrate 13 is preferably selected from the group consisting of silicon, SiAlON, sapphire, cordierite, mullite, glass, quartz, rock crystal, alumina, SUS, iron nickel alloy (42 alloy), and brass. Although the thickness of the support substrate 13 is, for example, 0.2 to 1 mm, another given proper thickness than these can be adopted.

The silicon may be single crystal silicon, may be polycrystal silicon, or may be high resistance silicon. Alternatively, the support substrate 13 may be SOI (Silicon on Insulator).

Typically, the SiAlON is ceramics obtained by sintering the mixture of silicon nitride and alumina, and has, for example, a composition represented by Si_{6-w}Al_{w}O_{w}N_{8-w}. Specifically, SiAlON has a composition obtained by mixing alumina in silicon nitride, and w in the formula represents the mixing ratio of alumina. w is preferably 0.5 or more and 4.0 or less.

Typically, the sapphire is a single crystalline body having the composition of Al₂O₃, and the alumina is a polycrystalline body having the composition of Al₂O₃. Alumina is preferably translucent alumina.

Typically, the cordierite is ceramics having a composition of 2MgO·2Al₂O₃·5SiO₂, and the mullite is ceramics having a composition within the range of 3Al₂O₃·2SiO₂ to 2Al₂O₃·SiO₂.

### Device

The structure of the shown joined body 1 can be used as each structure of various devices. Examples of the device may include a high-frequency device, a power semiconductor, a semiconductor laser, a surface acoustic wave filter (SAW (Surface Acoustic Wave) filter), and a thin film piezoelectric MEMS (Micro Electro Mechanical Systems).

### Description of Method for Manufacturing Joined Body 1

Next, a method for manufacturing the joined body 1 will be described.

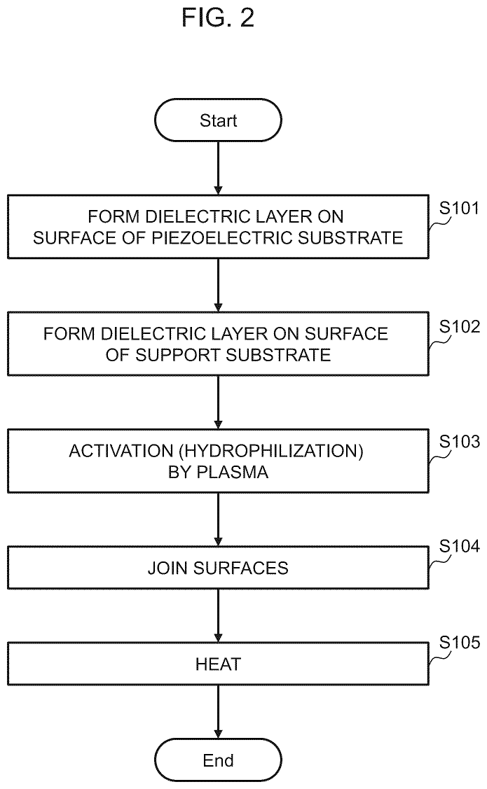

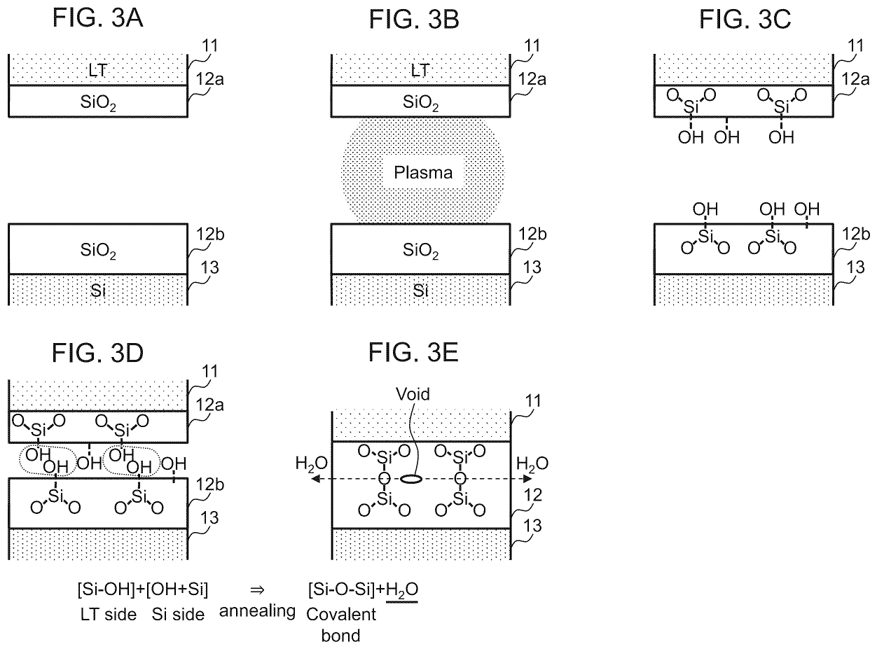

FIG. 2 is a flowchart for illustrating the method for manufacturing the joined body 1. Further, FIGS. 3A to 3E are each a view showing the state corresponding to each step shown in FIG. 2.

First, a piezoelectric material substrate 11 is prepared, and a dielectric layer 12a is formed at the surface of the piezoelectric material substrate 11 (Step 101). Further, the support substrate 13 is prepared, and a dielectric layer 12b is formed at the surface of the support substrate 13 (Step 102). Step 101 and Step 102 form dielectric layers 12a and 12b at the surfaces of the piezoelectric material substrate 11 and the support substrate 13 (dielectric layer forming step: FIG. 3A). Incidentally, Steps 101 and 102 may be interchanged in order. Further, herein, the “surface” is the main surface of the piezoelectric material substrate 11 or the support substrate 13, and is not the side surface thereof.

In the present embodiment, the piezoelectric material substrate 11 including the dielectric layer 12a formed therein is one example of the first substrate having a surface (surface layer) including SiO₂ as the main component. Further, the support substrate 13 including the dielectric layer 12b formed therein is one example of a second substrate having a surface (surface layer) including SiO₂ as the main component. Furthermore, in this case, it can also be said as follows: the first substrate is obtained by depositing SiO₂ on the piezoelectric material substrate 11, and the second substrate is obtained by depositing SiO₂ on the support substrate 13.

The dielectric layers 12a and 12b each include SiO₂ as the main component. The dielectric layers 12a and 12b are joined to be integrated in a later step, resulting in a dielectric layer 12 including SiO₂ as the main component. The dielectric layers 12a and 12b can be formed by reactive sputtering using a reactive sputtering apparatus. Specifically, in the reactive sputtering apparatus, the piezoelectric material substrate 11 and the support substrate 13 are arranged. Further, a target including silicon (Si) is arranged in the reactive sputtering apparatus. Further, an argon (Ar) gas and oxygen radicals are introduced into the reactive sputtering apparatus. Then, silicon configuring the target is sputtered by a sputtering power supply, thereby depositing a silicon film on the piezoelectric material substrate 11 and the support substrate 13, which is oxidized by oxygen radicals, resulting in a silicon oxide (SiO₂) film. As a result of this, it is possible to form the dielectric layers 12a and 12b each including SiO₂ as the main component on the surfaces of the piezoelectric material substrate 11 and the support substrate 13.

Incidentally, the dielectric layers 12a and 12b can also be polished to be planarized. As a result of this, the joint strength is improved for joining in a later step.

Next, respective surfaces of the dielectric layers 12a and 12b are activated by a plasma (Step 103: activating step) (FIG. 3B). As the plasma, a N₂ plasma can be used. As a result of this, as shown in FIG. 3C, SiO₂ configuring the dielectric layers 12a and 12b is activated, so that a hydroxy group (OH group) is generated as a hydrophilic functional group. Accordingly, the step can also be grasped as a hydrophilizing step of hydrophilizing respective surfaces of the dielectric layers 12a and 12b by a plasma.

Further, in the activating step, the discharge output of the plasma with respect to respective surfaces of the piezoelectric material substrate 11 and the support substrate 13 is preferably 30 to 100 W. When the discharge output of the plasma is equal to or larger than 30 W, the plasma is more stabilized, so that hydroxy groups are sufficiently generated, resulting in a more improvement of the joint strength in a later step. On the other hand, even when the discharge output of the plasma exceeds 100 W, the reflected wave of the plasma becomes larger, and the degree of activation is not changed, so that a further improvement of the joint strength cannot be expected. Accordingly, from the viewpoint of the efficiency, the discharge output of the plasma is preferably equal to or smaller than 100 W.

Further, the surfaces of the dielectric layers 12a and 12b after the activating step are joined with each other (Step 104: joining step) (FIG. 3D). Joining is performed by, for example, bringing the surfaces of the dielectric layers 12a and 12b into contact with each other, and pressing the dielectric layers 12a and 12b under a predetermined pressure. As a result of this, the piezoelectric material substrate 11 and the support substrate 13 are joined with each other via the dielectric layers 12a and 12b.

Further, at this step, joining is performed at a degree of vacuum of 1 mbar or more and 400 mbar or less.

Incidentally, this can also be said as joining being performed in the atmosphere at 1 mbar or more and 400 mbar or less. As a result of this, it is possible to manufacture the joined body 1 capable of combining the reduction of generation of voids and the joint strength. When the degree of vacuum is less than 1 mbar, the joint strength tends to become deficient. On the other hand, when the degree of vacuum exceeds 400 mbar, voids become more likely to be generated excessively.

Furthermore, the vacuum time of the joining step is preferably 30 to 120 seconds. When the vacuum time of the joining step is equal to or larger than 30 seconds, it becomes easier to control the amount of the OH groups by the degree of vacuum. For this reason, a preferable sufficient joint strength is ensured. Still further, when the vacuum time is equal to or smaller than 120 seconds, the particles to be deposited on the wafer surface are also suppressed, which is preferable.

Then, the joined piezoelectric material substrate 11 and support substrate 13 are heated (Step 105: heating step) (FIG. 3E). Heating is performed, for example, at a predetermined temperature and for a predetermined time by placing the joined piezoelectric material substrate 11 and support substrate 13 into a heating apparatus such as an oven. Heating causes the hydroxy groups generated on the surfaces of the dielectric layers 12a and 12b to be covalently bonded. Then, the dielectric layers 12a and 12b are integrated with each other, resulting in the dielectric layer 12. As a result of this, the piezoelectric material substrate 11 and the support substrate 13 are firmly bonded via the dielectric layer 12. Further, at this step, the reaction of [Si—OH]+[OH+Si]→[Si—O—Si]+H₂O is effected, so that water (H₂O) is generated. The water is discharged to outside the dielectric layer 12. When water is generated excessively, the water remains as voids in the dielectric layer 12.

Incidentally, the heating step can also be grasped as a step (annealing step) of subjecting the joined piezoelectric material substrate 11 and support substrate 13 to an annealing treatment.

Further, a step of grinding the piezoelectric material substrate 11 and the support substrate 13 after heating may be provided (grinding step). In the present embodiment, the piezoelectric material substrate 11 is ground into a thin film, thereby forming the piezoelectric layer 11a shown in FIG. 1. Incidentally, the edges of the piezoelectric material substrate 11 and the support substrate 13 may be ground. By the steps up to this point, the joined body 1 can be manufactured.

### EXAMPLES

### Example 1

As the piezoelectric material substrate 11, a 42Y-cut black LiTaO₃ (LT) substrate with a thickness of 0.25 mm, and with both surfaces mirror-polished was prepared. Further, as the support substrate 13, a high-resistance (≥2 kΩ·cm) Si substrate with a thickness of 0.23 mm was prepared.

Next, on the LT substrate and the Si substrate, SiO₂ films were deposited 0.5 μm as the dielectric layer 12a and the dielectric layer 12b, respectively (dielectric layer forming step), and the surface thereof was polished by about 0.1 μm by CMP (Chemical Mechanical Polishing) for planarization.

After activating the SiO₂ film surfaces of the LT substrate and the Si substrate by a N₂ plasma with a discharge output of 100 W (the LT substrate side), and 65 W (the Si substrate side) (activating step), joining was performed at a prescribed degree of vacuum (joining step). The degree of vacuum in the joining chamber at this step was 30.2 mbar. Further, the vacuum time at the joining step was 120 seconds.

For the purpose of increasing the joint strength, the joined substrates were charged into a 130° C. oven, and were heated for 4 hours (heating step). The LT surface of the joint substrate taken out from the oven was thinned to 1 μm by grinding and polishing.

As a result of this, the joined body 1 was manufactured, and the entire wafer surface was observed by a high-resolution outward appearance inspection apparatus.

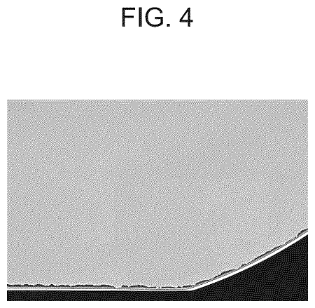

The results are shown in FIG. 4.

As shown in FIG. 4, voids were not generated, and further, the joint strength was also sufficient.

### Comparative Example 1

The joined body 1 was manufactured in the same manner as in Example 1, except for setting the degree of vacuum for joining the SiO₂ film surfaces of the LT substrate and the Si substrate at 1013 mbar (1 atm). Then, observation was performed in the same manner as in Example 1.

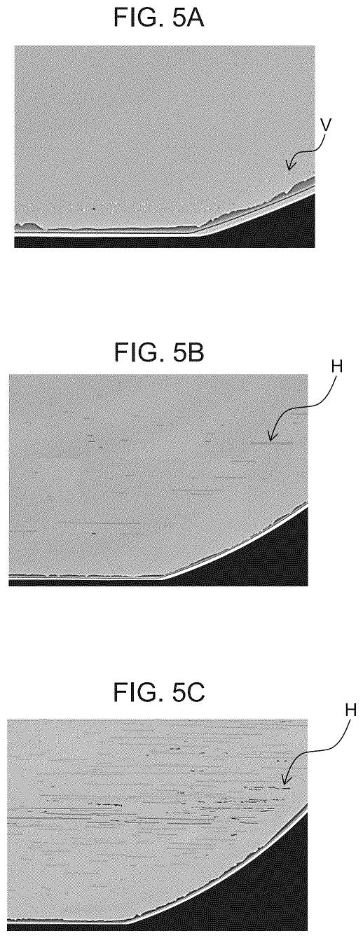

The results are shown in FIG. 5A.

As shown in FIG. 5A, it is indicated that excessive moisture is generated in the vicinity of the periphery in the form of a void V after heating. Incidentally, the joint strength was sufficient. This can be considered due to the fact that a too high degree of vacuum caused excessive moisture to be left at the joint interface.

### Comparative Example 2

The joined body 1 was manufactured in the same manner as in Example 1, except for setting the degree of vacuum for joining the SiO₂ film surfaces of the LT substrate and the Si substrate at 0.16 mbar. Then, observation was performed in the same manner as in Example 1.

The results are shown in FIG. 5B.

As shown in FIG. 5B, the moisture at the joint interface became deficient, so that peeling H was generated due to insufficient joint strength. This can be considered due to the fact that a too low degree of vacuum resulted in shortage of the moisture left at the joint interface, resulting in the shortage of OH groups for undergoing covalently bonding. Furthermore, also in Comparative Example 2, voids were generated in the whole wafer.

### Comparative Example 3

The joined body 1 was manufactured in the same manner as in Example 1, except for setting the degree of vacuum for joining the SiO₂ film surfaces of the LT substrate and the Si substrate at 0.0001 mbar. Then, observation was performed in the same manner as in Example 1.

The results are shown in FIG. 5C.

As shown in FIG. 5C, a large number of peeling Hs were generated due to the very small amount of moisture at the joint interface and the remarkably low joint strength. This can be considered due to the following fact. The degree of vacuum was further reduced relative to Comparative Example 2, so that the moisture left at the joint interface became further deficient, resulting in a further shortage of OH groups to undergo covalently bonding. Further, also regarding Comparative Example 3, voids were generated in the whole wafer.

Thus, it is indicated that the number of the voids and the joint strength depend upon the degree of vacuum at the joining step.

Further, the joined body 1 was manufactured by further changing the conditions for activating the SiO₂ film surfaces of the LT substrate and the Si substrate by a N₂ plasma, and the vacuum time and the degree of vacuum during joining.

The changed conditions are shown in Table 1 below. Herein, it is indicated that the plasma discharge output on the LT substrate side (plasma power (upper)), and the plasma discharge output on the Si substrate side (plasma power (lower)) at the time of activation, the vacuum time and the degree of vacuum at the time of joining were changed. Then, under respective conditions, the number of the voids was calculated. Incidentally, the number of the voids is the number in the whole wafer with a diameter of 150 mm.

Excessive presence of the voids results in a defective device. Herein, the case where the number of voids is equal to or smaller than 500 is referred to as a success, and the case where the number of the voids exceeds 500 is referred to as a failure. The number of the voids is shown as the void number in Table 1 below.

TABLE 1

| | | | | Degree of | |
|---|---|---|---|---|---|
| | Plasma | Plasma | Vacuum | vacuum | |
| | power | power | time during | during | |
| | (upper) | (lower) | joining | joining | Void |
| No | [W] | [W] | [sec] | [mbar] | number |
| 1 | 100 | 65 | 120 | 30.2 | 144 |
| 2 | 30 | 100 | 30 | 1.41 | 404 |
| 3 | 100 | 100 | 70.5 | 1000 | 972 |
| 4 | 68.5 | 100 | 30 | 269 | 10 |
| 5 | 100 | 44 | 79.5 | 12.6 | 9 |
| 6 | 65 | 72 | 70.5 | 1.41 | 40 |
| 7 | 58 | 100 | 120 | 12.6 | 35 |
| 8 | 100 | 79 | 30 | 1.41 | 96 |
| 9 | 68.5 | 30 | 30 | 1.41 | 142 |
| 10 | 30 | 58 | 30 | 1000 | 599 |
| 11 | 30 | 30 | 120 | 30.2 | 14 |
| 12 | 61.5 | 68.5 | 75 | 12.6 | 19 |
| 13 | 75.5 | 65 | 120 | 1000 | 913 |
| 14 | 61.5 | 68.5 | 75 | 8.13 | 69 |
| 15 | 30 | 30 | 48 | 1.41 | 241 |
| 16 | 30 | 68.5 | 120 | 0.16 | 2177 |
| 17 | 100 | 100 | 120 | 0.16 | 1463 |
| 18 | 93 | 30 | 120 | 0.16 | 1737 |
| 19 | 30 | 100 | 97.5 | 1000 | 1046 |

In Table 1, Nos. 1 to 2, 4 to 9, 11 to 12, and 14 to 15 are each referred to as a success, and others are each referred to as a failure. The results up to this point indicate that the number of the voids mainly depends upon the degree of vacuum.

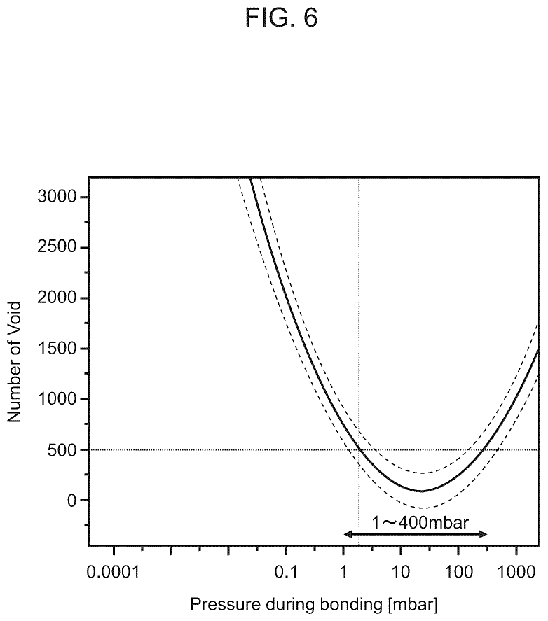

FIG. 6 is a view showing the relationship between the degree of vacuum and the number of the voids.

In FIG. 6, the horizontal axis represents the degree of vacuum, and the vertical axis represents the number of the voids. Then, it is indicated that the number of the voids with respect to a prescribed degree of vacuum falls within the range interposed by mainly dotted lines.

As shown, when the degree of vacuum at the time of joining is 1 mbar or more and 400 mbar or less, the number of the voids falls within the range of 500 or less. On the other hand, when the degree of vacuum is less than 1 mbar and more than 400 mbar, the number of the voids tends to exceed 500. In other words, by performing joining under an atmosphere with the degree of vacuum, it is possible to make the moisture amount at the joint interface proper. At the time of joining, the atmosphere with the degree of vacuum is achieved, thereby reducing the moisture adsorbing the joint interface, and suppressing the voids after heating. On the other hand, there is achieved the degree of vacuum at which the moisture necessary for guaranteeing the joint strength is kept.

According to the results up to this point, the degree of vacuum of the joining step is preferably determined by the joint strength between the LT substrate and the Si substrate, and the degree of the voids generated at the joint surface after the heating step.

Further, for the activating step, the discharge output of the plasma with respect to respective surfaces of the first substrate and the second substrate is preferably determined by the joint strength and the degree of the voids after the heating step.

Incidentally, although the foregoing steps were described as the method for manufacturing the joined body 1, they can also be grasped as the method for joining two SiO₂ layers. In other words, the foregoing steps can also be grasped as the joining method including an activating step of activating respective surfaces of the first SiO₂ layer (in the foregoing example, the dielectric layer 12a) and the second SiO₂ layer (in the foregoing example, the dielectric layer 12b) by a plasma; a joining step of joining the surfaces of the first SiO₂ layer and the second SiO₂ layer at a degree of vacuum of 1 mbar or more and 400 mbar or less; and a heating step of heating the joined first SiO₂ layer and second SiO₂ layer, and removing water generated at the joint surface in this order.

Up to this point, the present embodiment was described. However, the technical scope of the present invention is not limited to the scope described in the embodiments. It is obvious from the description of the appended claims that variously changed or improved embodiments described above are also included in the technical scope of the present invention.

### REFERENCE SIGNS LIST

1 Joined body
11 Piezoelectric material substrate
11a Piezoelectric layer
12, 12a, 12b Dielectric layer
13 Support substrate
V Void
H Peeling

1. A method for manufacturing a joined body, the method comprising:
an activating step of activating respective surfaces of a first substrate and a second substrate having the surfaces each including SiO₂ as a main component by a plasma;
a joining step of joining the surfaces of the first substrate and the second substrate at a degree of vacuum of 1 mbar or more and 400 mbar or less; and
a heating step of heating the first substrate and the second substrate joined with each other, in this order;
for the activating step, a discharge output of the plasma with respect to the respective surfaces of the first substrate and the second substrate is 30 to 100 W;
the first substrate is obtained by depositing SiO₂ on a piezoelectric material substrate, and the second substrate is obtained by depositing SiO₂ on a support substrate.

2. The method for manufacturing a joined body according to claim 1, wherein
a vacuum time of the joining step is 30 to 120 seconds.

3. The method for manufacturing a joined body according to claims 1, further comprising a grinding step of grinding the first substrate after heating.

4. A joining method comprising:
an activating step of activating respective surfaces of a first SiO₂ layer and a second SiO₂ layer by a plasma;
a joining step of joining the surfaces of the first SiO₂ layer and the second SiO₂ layer at a degree of vacuum of 1 mbar or more and 400 mbar or less; and
a heating step of heating the first SiO₂ layer and the second SiO₂ layer joined with each other, and removing water generated at a joint surface thereof, in this order;
for the activating step, a discharge output of the plasma with respect to the respective surfaces of the first substrate and the second substrate is 30 to 100 W.
